(19) United States
(12) Patent Application Publication
(10) Pub. No.: US 2011/0071780 A1
(43) Pub. Date: Mar. 24, 2011

(54) METHOD AND APPARATUS FOR DISPLAYING AT LEAST ONE INDICATOR RELATED TO A PROJECTED BATTERY LIFESPAN

(75) Inventor: Sasu Tarkoma, Helsinki (FI)

(73) Assignee: NOKIA CORPORATION, Espoo (FI)

(21) Appl. No.: 12/563,768

(22) Filed: Sep. 21, 2009

(51) Int. Cl. G01R 31/36

(52) U.S. Cl. 702/63

(57) ABSTRACT

In accordance with an example embodiment of the present invention, the apparatus comprises at least one processor and at least one memory including computer program code. The at least one memory and the computer program code configured to, with the at least one processor, cause the apparatus to perform at least the following determine an estimated battery usage for one or more activities. Further, a user interface is configured to display at least one indicator related to a projected battery lifespan based at least in part on the estimated battery usage of the one or more activities.

### TECHNICAL FIELD

The present application relates generally to displaying at least one indicator related to a projected battery lifespan.

### BACKGROUND

An electronic device may have a display to view information. Further, there may be different types of information to display. As such, the electronic device facilitates displaying of different information.

### SUMMARY

Various aspects of examples of the invention are set out in the claims.

According to a first aspect of the present invention, the apparatus comprises at least one processor and at least one memory including computer program code. The at least one memory and the computer program code configured to, with the at least one processor, cause the apparatus to perform at least the following determine an estimated battery usage for one or more activities. Further, a user interface is configured to display at least one indicator related to a projected battery lifespan based at least in part on the estimated battery usage of the one or more activities.

According to a second aspect of the present invention, a method comprises determining an estimated battery usage for one or more activities and displaying at least one indicator related to a projected battery lifespan using a user interface based at least in part on the estimated battery usage of the one or more activities.

### BRIEF DESCRIPTION OF THE DRAWINGS

For a more complete understanding of example embodiments of the present invention, reference is now made to the following descriptions taken in connection with the accompanying drawings in which:

FIG. 1 is a block diagram depicting an electronic device operating in accordance with an example embodiment of the invention;

FIG. 2 is a block diagram depicting an electronic device operating in accordance with an example embodiment of the invention;

FIG. 3 is a block diagram depicting a user interface operating in accordance with an example embodiment of the invention;

FIG. 4 is a block diagram depicting another user interface operating in accordance with an example embodiment of the invention;

FIG. 5 is a flow diagram depicting an example method operating in accordance with an example embodiment of the invention; and

FIGS. 6A-6B are block diagrams depicting a notification on a user interface operating in accordance with an example embodiment.

### DETAILED DESCRIPTION OF THE DRAWINGS

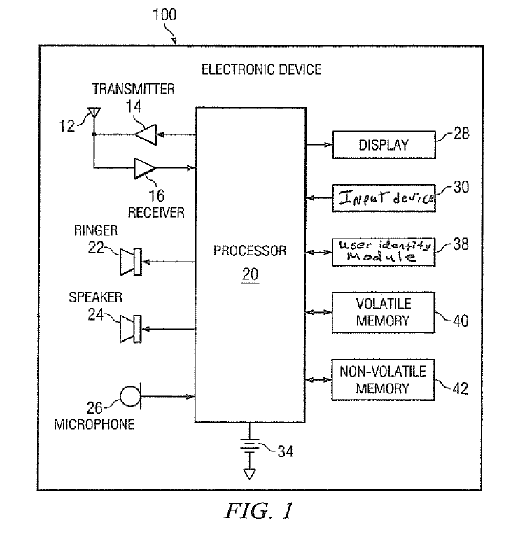

An example embodiment of the present invention and its potential advantages are understood by referring to FIGS. 1 through 6B of the drawings.

FIG. 1 is a block diagram depicting an electronic device 100 operating in accordance with an example embodiment of the invention. In an example embodiment, an electronic device 100 comprises at least one antenna 12 in communication with a transmitter 14, a receiver 16, and/or the like. The electronic device 100 may further comprise a processor 20 or other processing component. In an example embodiment, the electronic device 100 may comprises multiple processors, such as processor 20. The processor 20 may provide at least one signal to the transmitter 14 and may receive at least one signal from the receiver 16. In an embodiment, the electronic device 100 may also comprise a user interface comprising one or more input or output devices, such as a conventional earphone or speaker 24, a ringer 22, a microphone 26, a display 28, and/or the like. In an embodiment, an input device 30 comprises a mouse, a touch screen interface, a pointer, and/or the like. In an embodiment, the one or more output devices of the user interface may be coupled to the processor 20. In an example embodiment, the display 28 is a touch screen, liquid crystal display, and/or the like.

In an embodiment, the electronic device 100 may also comprise a battery 34, such as a vibrating battery pack, for powering various circuits to operate the electronic device 100. Further, the vibrating battery pack may also provide mechanical vibration as a detectable output. In an embodiment, the electronic device 100 may further comprise a user identity module (UIM) 38. In one embodiment, the UIM 38 may be a memory device comprising a processor. The UIM 38 may comprise, for example, a subscriber identity module (SIM), a universal integrated circuit card (UICC), a universal subscriber identity module (USIM), a removable user identity module (R-UIM), and/or the like. Further, the UIM 38 may store one or more information elements related to a subscriber, such as a mobile subscriber.

In an embodiment, the electronic device 100 may comprise memory. For example, the electronic device 100 may comprise volatile memory 40, such as random access memory (RAM). Volatile memory 40 may comprise a cache area for the temporary storage of data. Further, the electronic device 100 may also comprise non-volatile memory 42, which may be embedded and/or may be removable. The non-volatile memory 42 may also comprise an electrically erasable programmable read only memory (EEPROM), flash memory, and/or the like. In an alternative embodiment, the processor 20 may comprise memory. For example, the processor 20 may comprise volatile memory 40, non-volatile memory 42, and/or the like.

In an embodiment, the electronic device 100 may use memory to store any of a number of pieces of information and/or data to implement one or more features of the electronic device 100. Further, the memory may comprise an identifier, such as international mobile equipment identification (IMEI) code, capable of uniquely identifying the electronic device 100. The memory may store one or more instructions for determining cellular identification information based at least in part on the identifier. For example, the processor 20, using the stored instructions, may determine an identity, e.g., cell id identity or cell id information, of a communication with the electronic device 100.

In an embodiment, the processor 20 of the electronic device 100 may comprise circuitry for implementing audio feature, logic features, and/or the like. For example, the processor 20 may comprise a digital signal processor device, a microprocessor device, a digital to analog converter, other support circuits, and/or the like. In an embodiment, control and signal processing features of the processor 20 may be allocated between devices, such as the devices describe above, according to their respective capabilities. Further, the processor 20 may also comprise an internal voice coder and/or an internal data modem. Further still, the processor 20 may comprise features to operate one or more software programs. For example, the processor 20 may be capable of operating a software program for connectivity, such as a conventional Internet browser. Further, the connectivity program may allow the electronic device 100 to transmit and receive Internet content, such as location-based content, other web page content, and/or the like. In an embodiment, the electronic device 100 may use a wireless application protocol (WAP), hypertext transfer protocol (HTTP), file transfer protocol (FTP) and/or the like to transmit and/or receive the Internet content.

In an embodiment, the electronic device 100 may be capable of operating in accordance with any of a number of a first generation communication protocol, a second generation communication protocol, a third generation communication protocol, a fourth generation communication protocol, and/or the like. For example, the electronic device 100 may be capable of operating in accordance with second generation (2G) communication protocols IS-136, time division multiple access (TDMA), global system for mobile communication (GSM), IS-95 code division multiple access (CDMA), and/or the like. Further, the electronic device 100 may be capable of operating in accordance with third-generation (3G) communication protocols, such as Universal Mobile Telecommunications System (UMTS), CDMA2000, wideband CDMA (WCDMA), time division-synchronous CDMA (TD-SCDMA), and/or the like. Further still, the electronic device 100 may also be capable of operating in accordance with 3.9 generation (3.9G) wireless communication protocols, such as Evolved Universal Terrestrial Radio Access Network (E-UTRAN) or the like, or wireless communication projects, such as long term evolution (LTE) or the like. Still further, the electronic device 100 may be capable of operating in accordance with fourth generation (4G) communication protocols.

In an alternative embodiment, the electronic device 100 may be capable of operating in accordance with a non-cellular communication mechanism. For example, the electronic device 100 may be capable of communication in a wireless local area network (WLAN), other communication networks, and/or the like. Further, the electronic device 100 may communicate in accordance with techniques, such as radio frequency (RF), infrared (IrDA), any of a number of WLAN techniques. For example, the electronic device 100 may communicate using one or more of the following WLAN techniques: IEEE 802.11, e.g., 802.11a, 802.11b, 802.11g, 802.11n, and/or the like. Further, the electronic device 100 may also communicate, via a world interoperability, to use a microwave access (WiMAX) technique, such as IEEE 802.16, and/or a wireless personal area network (WPAN) technique, such as IEEE 802.15, BlueTooth (BT), ultra wideband (UWB), and/or the like.

It should be understood that the communications protocols described above may employ the use of signals. In an example embodiment, the signals comprises signaling information in accordance with the air interface standard of the applicable cellular system, user speech, received data, user generated data, and/or the like. In an embodiment, the electronic device 100 may be capable of operating with one or more air interface standards, communication protocols, modulation types, access types, and/or the like. It should be further understood that the electronic device 100 is merely illustrative of one type of electronic device that would benefit from embodiments of the invention and, therefore, should not be taken to limit the scope of embodiments of the invention.

While embodiments of the electronic device 100 are illustrated and will be hereinafter described for purposes of example, other types of electronic devices, such as a portable digital assistant (PDA), a pager, a mobile television, a gaming device, a camera, a video recorder, an audio player, a video player, a radio, a mobile telephone, a traditional computer, a portable computer device, a global positioning system (GPS) device, a GPS navigation device, a GPS system, a mobile computer, a browsing device, an electronic book reader, a combination thereof, and/or the like, may be used. While several embodiments of the invention may be performed or used by the electronic device 100, embodiments may also be employed by a server, a service, a combination thereof, and/or the like.

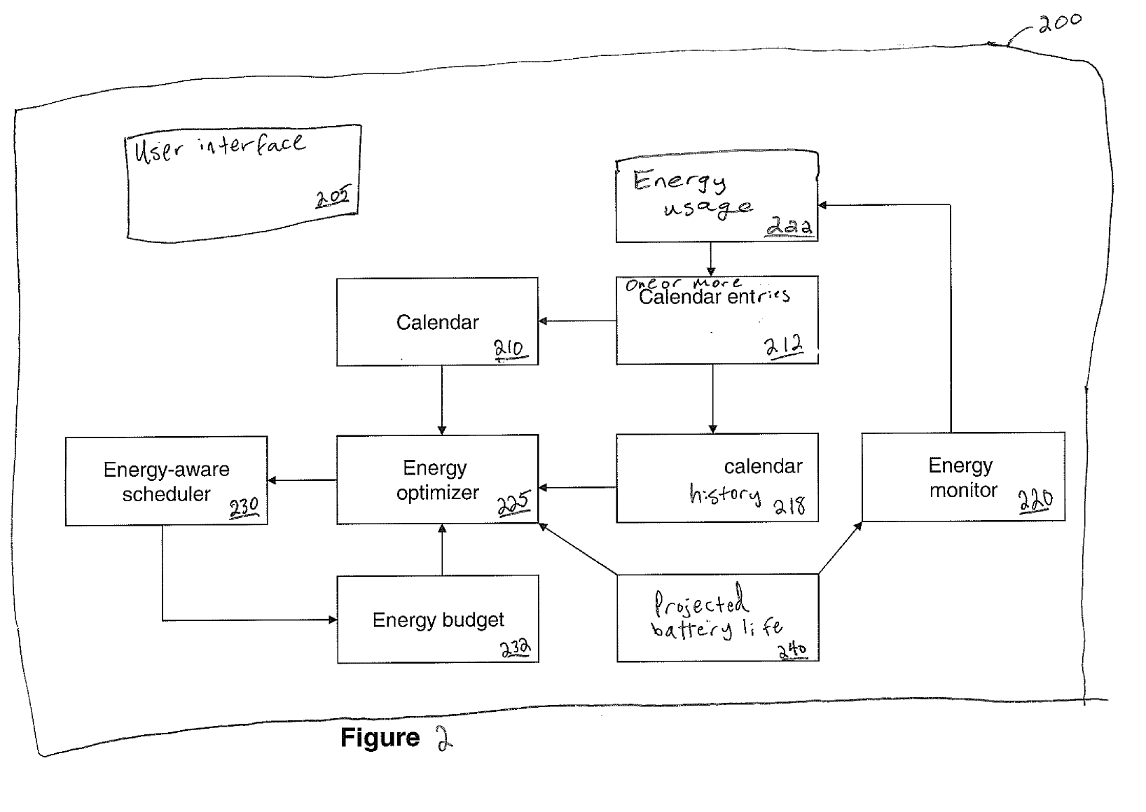

FIG. 2 is a block diagram depicting an electronic device 200 operating in accordance with an example embodiment of the invention. In an example embodiment, the electronic device 200 is similar to the electronic device 100 of FIG. 1. In an alternative embodiment, electronic device 200 is different than the electronic device 100 of FIG. 1.

In an example embodiment, the electronic device 200 comprises a user interface 205, a calendar 210, one or more sensors 215, an energy monitor 220, an energy optimizer 225, an energy-aware scheduler 230, and/or the like. In an example embodiment, the user interface 205 is configured to display at least one indicator related to a projected battery lifespan based at least in part on an estimated battery usage of the one or more activities. In an embodiment, the calendar 210 comprises one or more calendar entries 212 in memory for example. Each of the one or more calendar entries 212 may be associated with context information. In an embodiment, the context information comprises one or more dimensions, for example a time interval may be classified into central processing unit-intensive activity, a networking intensive activity, a combination thereof, and/or the like. A time interval may also be associated with an expected energy consumption distribution, for example, a histogram. In an example embodiment, a histogram is a graphical display of tabulated frequencies. In an embodiment, the histogram relates to a proportion of cases, which fall into each of several categories, e.g., a form of data binning. The categories may be specified as non-overlapping intervals of some variable. The categories (bars) are generally adjacent. The intervals, bands, bins, and/or the like are generally about the same size.

In an example embodiment, the one or more sensors 215 are configured to monitor the environment of the electronic device 200. Further, the one or more sensors 215 are configured to store current context based at least in part on time and/or current calendar events.

In an embodiment, the energy monitor 220 is configured to monitor current energy consumption. Further, the energy monitor 220 is configured to log or otherwise note energy consumption per certain configurable time interval. The logged information may be stored in the calendar history 218, e.g., a history of calendar events. In an example embodiment, the energy monitor 220 is configured to associate time intervals, such as calendar entries, with energy usage, communications, central processing unit usage distributions, and/or the like. The associated information may be stored in the calendar log, and associated with any existing calendar entries. The calendar entries may also have optional context information, such as location.

In an example embodiment, the energy optimizer 225 is configured to receive an energy budget 232. Further, the energy optimize 225 is configured to review the one or more calendar entries 212 to estimate energy consumption. In an embodiment, historical observations are with the one or more calendar entries 212 to determine a projected battery life 240. In an embodiment, the user interface 205 is configured to display the projected battery life 240 based at least in part on the energy optimizer 225 association. For example, the user interface 205 graphically indicates the expected running time in the calendar or other convenient location, for example the battery indicator.

In an embodiment, the energy optimizer 225 is configured to comprise an energy budget 232. The energy budget may be used to determine energy consumption policies for the electronic device. For example the energy budget 232 may specify that the electronic device may operate for 48 hours. In an embodiment, the energy optimizer 225 uses a calendar 210 to estimate near-future energy consumption. In an embodiment, the energy optimizer 225 determines the next expected charging time for the electronic device, and it may be able to estimate how the central processing unit and/or data communications will be used.

In an example embodiment, the energy-aware scheduler 230 estimates based at least in part on the current energy consumption, observed past energy consumption, anticipated future energy consumption, and/or the like. The current energy consumption may be derived from information provided by the battery, operating system, subsystems, and/or the like. A signature of the current energy consumption may be stored in the electronic device and/or associated with the current operating context. The anticipated future energy consumption is estimated by the examining the past energy consumption in the same or similar context, and then improving the estimate by taking additional information into account, such as information provided by the calendar on meetings, travels, locations, and/or the like. In such a case, these estimates may be used to configure the energy-aware scheduler 230.

In an example embodiment, the user interface 205 displays to the user how many hours the device is expected to be fully operational. In an embodiment, the energy optimizer 225 determines priority of scheduled applications, processes, and/or the like. For example, the energy optimizer 225 may delay some communications, and/or issue a request to stop one or more activities. In an example embodiment, the energy-aware scheduler 230 is configured by the energy optimizer 225. The energy optimizer 225 may prioritize some processes and allow one or more activities are paused in order to be able to save energy. In an example embodiment, the user interface 205 using the energy optimizer 225 information, may augment the calendar and/or the battery indicator by displaying the expected time until battery exhaustion.

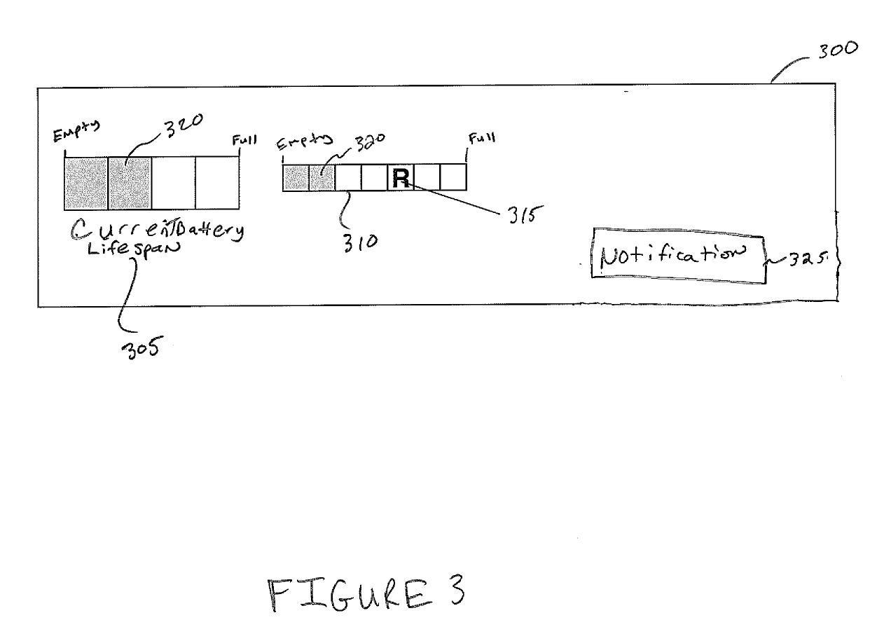

FIG. 3 is a block diagram depicting a user interface 300 operating in accordance with an example embodiment of the invention. In an example embodiment, the user interface 300 is part on an apparatus, such as electronic device 100 of FIG. 1.

In an embodiment, the apparatus comprises at least one processor and at least one memory including computer program code. The at least one memory and the computer program code configured to, with the at least one processor, cause the apparatus to perform at least the following: determine an estimated battery usage for one or more activities. In an embodiment, the at least one processor, further causes the apparatus to perform at least the following receive a user configuration associated to battery usage. In an example embodiment, the at least one processor, further causes the apparatus to perform at least the following associate the battery usage to the one or more activities. In an example embodiment, the one or more activities are at least one of the following: calendar entry, content download, telephone conference, travel, a combination thereof, and/or the like.

The apparatus further comprises a user interface 300 configured to display at least one indicator related to a projected battery lifespan 310 based at least in part on the estimated battery usage of the one or more activities. In an embodiment, the user interface 300 is further configured to display a notification related to a projected battery lifespan 310. In an example embodiment, the user interface 300 is further configured to display multiple indicators related to the projected battery lifespan 310 based at least in part on the configuration. For example, the user interface 300 displays a projected battery lifespan 310, one or more suggestions to conserve battery life, a notification to conserve battery life, and/or the like.

In an example embodiment, the projected battery lifespan 310 is calculated based at least in part on at least one of prior usage. In an alternative embodiment, the projected battery lifespan 310 is calculated based at least in part on user input. In yet another embodiment, the projected battery lifespan 310 is calculated using a highest possible usage. In an example embodiment, the user interface 300 is further configured to display at least one of one or more user hints related to energy consumption for the one or more activities.

In an example embodiment, the user interface 300 displays a current battery lifespan 305, the projected battery lifespan 310, one or more indicators 315, 320, a notification, and/or the like. In an example embodiment, the user interface 300 displays an indicator 320 representing full, partially full, empty, and/or the like. For example, the user interface 300 displays a color and/or other representation related to battery life. In an example embodiment, the user interface displays an indicator 315 indicating a user should consider recharging the electronic device. In such a case, the user may quickly identify when recharging is to be performed. It should be understood that the user interface 300 may display as part of a battery indicator, a calendar, and/or the like.

In an example embodiment, the user interface 300 displays a notification 325 to a user. In an embodiment, a notification 325 is used to inform a user on the current and expected battery lifetime. In an example, explicit notifications are not expected to be used when there is sufficient battery life available. Example embodiments determine that the remaining battery lifespan is not be able to support currently on-going activities or expected activities in the near-future, such as telephone conference. In such a case, the notification 325 is used to inform the user that either one or more activities should be postponed, or that the battery needs to be recharged. In an embodiment, a notification 325 involves a dialog. The dialog indicates near-future activities and informs the user that battery will run out during these activities, and propose battery charging.

In an embodiment, the notification 325 is an icon representing the application that is taking the most energy. The notification 325 may also use the user interface 300 interactively to allow the user to decide how to best utilize the remaining battery lifetime. The form of the user interface 300 may be a configuration parameter. One example of the user interface 300 is to present the currently running applications and a notification 325 indicating that one or more applications should be suspended to run an application longer in the future. Another user interface 300 example allows the user to select which activities in the future should have priority. Example embodiments may formulate a power management strategy to attempt to ensure that these user selected activities have sufficient battery lifespan.

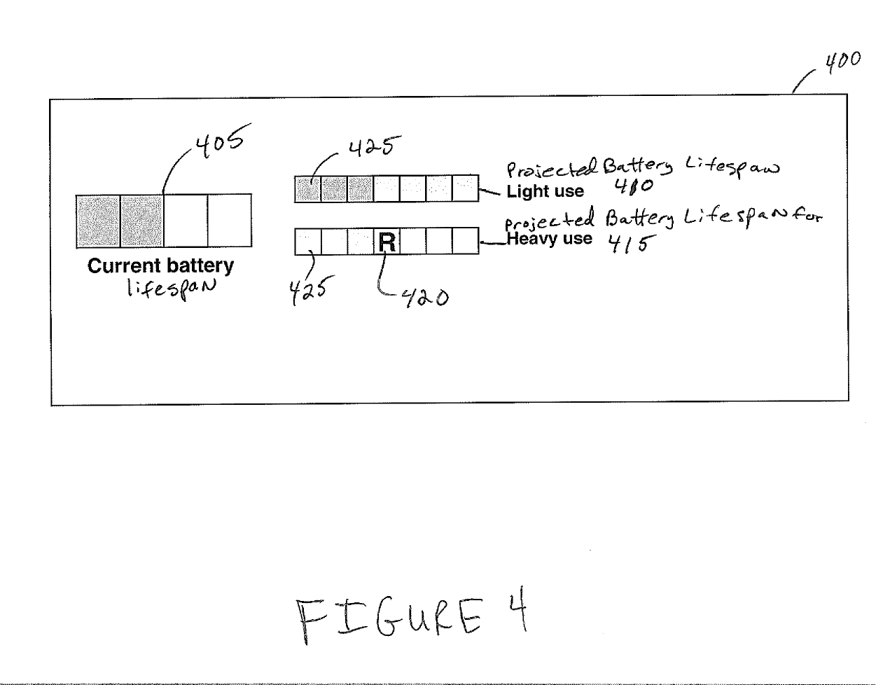

FIG. 4 is a block diagram depicting another user interface 400 operating in accordance with an example embodiment of the invention.

In an example embodiment, the user interface 400 displays a current battery lifespan 405, multiple projected battery lifespans 410, 415, one or more indicators 420, 425, and/or the like. In an example embodiment, the user interface 400 displays an indicator 425 representing full, partially full, empty, and/or the like. For example, the user interface 400 displays a color and/or other representation related to battery life.

In an example embodiment, the user interface displays an indicator 420 indicating a user should consider recharging. In such a case, the user may quickly identify when recharging is to be performed. In an embodiment, the user interface 400 displays on a battery usage screen, calendar, and/or the like. In an embodiment, the user interface 400 displays projected battery lifespan 410 for light use and/or projected battery lifespan 415 for heavy use. In such a case, the light or heavy use may be related to a lack of calendar entries. It should be understood that the user interface 400 may display as part of a battery indicator, a calendar, and/or the like.

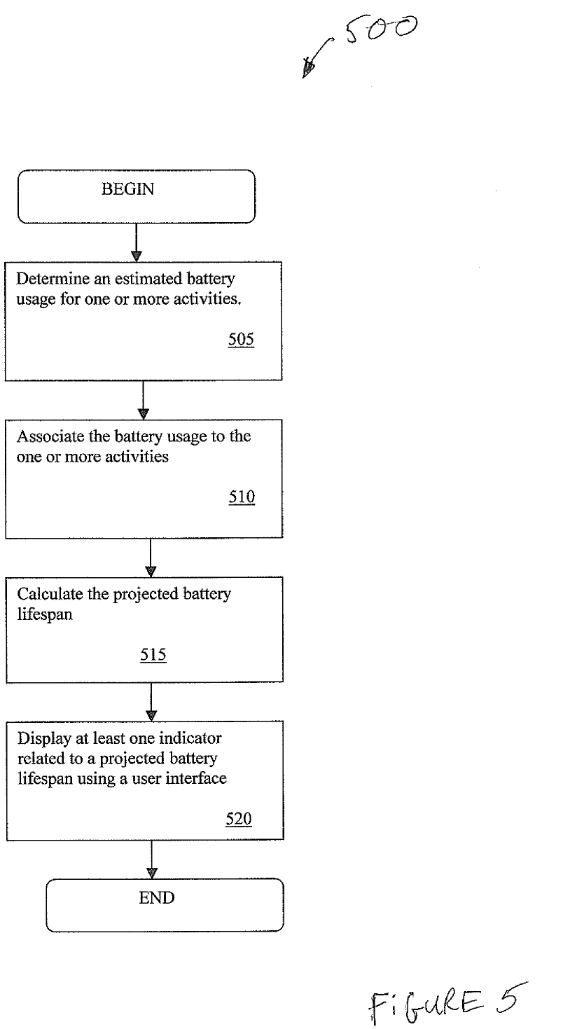

FIG. 5 is a flow diagram depicting an example method 500 operating in accordance with an example embodiment of the invention. Example method 500 may be performed by an electronic device, such as electronic device 100 of FIG. 1.

At 505, an estimated battery usage for one or more activities is determined. In an example embodiment, an energy optimizer, such as energy optimizer 225 of FIG. 2, is configured to determine an estimated battery usage for one or more activities. For example, the energy optimizer determines a teleconference uses an identified percentage of battery life.

At 510, the battery usage is associated to the one or more activities. In an example embodiment, a processor, such as processor 20 of FIG. 1, is configured to associate the battery usage to the one or more activities. For example, the processor associates ten percent battery usage for a one hour teleconference.

At 515, the projected battery lifespan is calculated. In an example embodiment, the processor calculates the projected battery lifespan based at least in part on the one or more activities. For example, the processor calculates a projected battery life of one hour based on the estimated usage of three teleconferences.

At 520, at least one indicator related to a projected battery lifespan using a user interface is displayed. In an example embodiment, the user interface, such as user interface 205 of FIG. 2, is configured to display at least one indicated related to the projected battery lifespan based at least in part on the estimated battery usage of the one or more activities. For example, the user interface displays an indicator related to time remaining for the projected battery lifespan. The example method 500 ends.

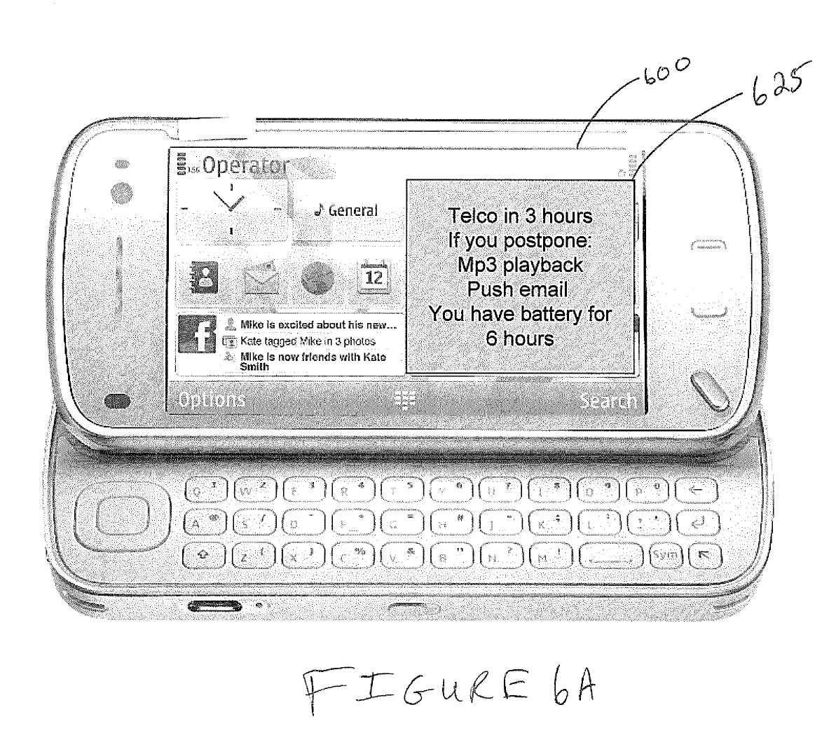

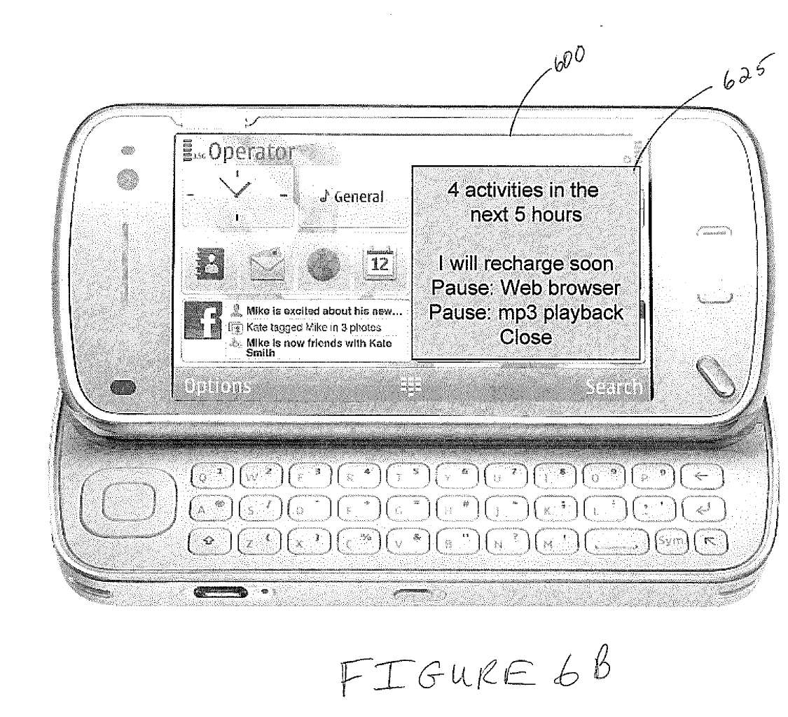

FIGS. 6A-6B are block diagrams depicting a notification 625 on a user interface 600 operating in accordance with an example embodiment.

In an embodiment, an electronic device, such as electronic device 100 of FIG. 1, comprises a user interface 600. The user interface is configured to display a notification 625. In an embodiment, the notification 625 is an icon representing the application that is taking the most energy. The notification 625 may also use the user interface 600 interactively to allow the user to decide how to best utilize the remaining battery lifetime. In an embodiment, the form of the user interface 600 may be a configuration parameter. One example of the user interface 600 is to present the currently running applications and a notification 625 indicating that one or more applications should be suspended to run an application longer in the future as shown in FIG. 6A. Another user interface 600 example allows the user to select which activities in the future should have priority as shown in FIG. 6B. Example embodiments may formulate a power management strategy to attempt to ensure that these user selected activities have sufficient battery lifespan.

Without in any way limiting the scope, interpretation, or application of the claims appearing below, a technical effect of one or more of the example embodiments disclosed herein is displaying one or more indicators based at least in part on a projected battery lifespan. Another technical effect of one or more of the example embodiments disclosed herein is automatically adjusting battery usage based at least in part on user information. Another technical effect of one or more of the example embodiments disclosed herein is automatically adjusting battery usage based at least in part prior usage.

Embodiments of the present invention may be implemented in software, hardware, application logic or a combination of software, hardware and application logic. The software, application logic and/or hardware may reside on an electronic device, a computer, or a service. If desired, part of the software, application logic and/or hardware may reside on an electronic device, part of the software, application logic and/or hardware may reside on a computer, and part of the software, application logic and/or hardware may reside on a service. In an example embodiment, the application logic, software or an instruction set is maintained on any one of various conventional computer-readable media. In the context of this document, a “computer-readable medium” may be any media or means that can contain, store, communicate, propagate or transport the instructions for use by or in connection with an instruction execution system, apparatus, or device, such as a computer, with one example of a computer described and depicted in FIG. 3. A computer-readable medium may comprise a computer-readable storage medium that may be any media or means that can contain or store the instructions for use by or in connection with an instruction execution system, apparatus, or device, such as a computer.

If desired, the different functions discussed herein may be performed in a different order and/or concurrently with each other. Furthermore, if desired, one or more of the above-described functions may be optional or may be combined.

Although various aspects of the invention are set out in the independent claims, other aspects of the invention comprise other combinations of features from the described embodiments and/or the dependent claims with the features of the independent claims, and not solely the combinations explicitly set out in the claims.

It is also noted herein that while the above describes example embodiments of the invention, these descriptions should not be viewed in a limiting sense. Rather, there are several variations and modifications which may be made without departing from the scope of the present invention as defined in the appended claims.

What is claimed is:

1. An apparatus, comprising:
at least one processor; and
at least one memory including computer program code
the at least one memory and the computer program code configured to, with the at least one processor, cause the apparatus to perform at least the following
determine an estimated battery usage for one or more activities; and
a user interface configured to:
display at least one indicator related to a projected battery lifespan based at least in part on the estimated battery usage of the one or more activities.

2. The apparatus of claim 1 wherein the one or more activities is at least one of the following: calendar entry, content download, telephone conference, travel, or a combination thereof.

3. The apparatus of claim 1 wherein the user interface is further configured to display a notification related to a projected battery lifespan.

4. The apparatus of claim 1 wherein the user interface is further configured to display multiple indicators related to the projected battery lifespan based at least in part on the configuration.

5. The apparatus of claim 1 wherein the at least one processor, further causes the apparatus to perform at least the following receive a user configuration associated to battery usage.

6. The apparatus of claim 1 wherein the projected battery lifespan is calculated based at least in part on at least one of prior usage.

7. The apparatus of claim 1 wherein the projected battery lifespan is calculated based at least in part on user input.

8. The apparatus of claim 1 wherein the projected battery lifespan is calculated using a highest possible usage.

9. The apparatus of claim 1 further comprising the at least one processor, further causes the apparatus to perform at least the following associate the battery usage to the one or more activities.

10. The apparatus of claim 1 wherein the user interface is further configured to display at least one of one or more user hints related to energy consumption for the one or more activities.

11. A method, comprising:
determining an estimated battery usage for one or more activities; and
displaying at least one indicator related to a projected battery lifespan using a user interface based at least in part on the estimated battery usage of the one or more activities.

12. The method of claim 11 wherein the one or more activities is at least one of the following: calendar entry, content download, telephone conference, travel, or a combination thereof.

13. The method of claim 11 further comprising displaying a notification related to a projected battery lifespan.

14. The method of claim 11 further comprising displaying multiple indicators related to the projected battery lifespan based at least in part on the configuration.

15. The method of claim 11 further comprising receiving a user configuration associated to battery usage.

16. The method of claim 11 further comprising calculating the projected battery lifespan based at least in part on at least one of prior usage.

17. The method of claim 11 further comprising calculating projected battery lifespan based at least in part on user input.

18. The method of claim 11 further comprising calculating the projected battery lifespan a highest possible usage.

19. The method of claim 11 further comprises associating the battery usage to the one or more activities.

20. The method of claim 11 further comprising displaying at least one of one or more user hints related to energy consumption for the one or more activities.
